(19) United States
(12) Patent Application Publication
(10) Pub. No.: US 2010/0171179 A1
(43) Pub. Date: Jul. 8, 2010

(54) FULL PERIPHERY MULTI-GATE TRANSISTOR WITH OHMIC STRIP

(75) Inventors: Shih Ming LIU, Taipei City (TW); Cheng Guan YUAN, Taipei City (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: WIN SEMICONDUCTORS CORP., Tao Yuan Shien (TW)

(21) Appl. No.: 12/349,090

(22) Filed: Jan. 6, 2009

(51) Int. Cl. H01L 29/78

(52) U.S. Cl. 257/365; 257/E29.264

(57) ABSTRACT

A full periphery multi-gate transistor with ohmic strip is disclosed. The multi-gate transistor comprises a substrate, a multi-layer structure, a source finger, a drain finger, and a gate. The gate is formed between the source finger and the drain finger, and then a conduction channel is formed between the source finger and the drain finger. The gate also meanderingly wraps around an end of the source finger and an end of the drain finger. Therefore, the end of the source finger and the end of the drain finger are parts of the conduction channel and both provide channel conductance. In addition, an ohmic strip is formed between two gate lines of the gate.

### BACKGROUND OF THE INVENTION

1. Field of the Invention

The invention relates to a transistor, and more particularly, to a full periphery multi-gate transistor with ohmic strip.

2. Description of the Prior Art

Planar transistors have been the core of integrated circuits for several decades, during which the size of the individual transistors has steadily decreased. At the current pace of scaling, the industry predicts that planar transistors will reach feasible limits of miniaturization by 2010, concurrent with the widespread adoption of 32 nm technologies. At such sizes, planar transistors are expected to suffer from undesirable short channel effects, especially “off-state” leakage current, which increases the idle power required by the device.

A multi-gate transistor refers to a MOSFET which incorporates more than one gate into a single device. The multiple gates may be controlled by a single gate electrode, wherein the multiple gate surfaces act electrically a single gate, or by independent gate electrodes. Multi-gate transistor is one of several strategies being developed by CMOS semiconductor manufacturers to create ever-smaller microprocessors and memory cells, colloquially referred to as extending Moore's Law. Development efforts into multi-gate transistors have been reported by AMD, Hitachi, IBM, Infineon, Intel, TSMC, and other companies.

In a multi-gate transistor, the conduction channel is surrounded by several gates on multiple surfaces, allowing more effective suppression of “off-state” leakage current. Multiple gates also allow enhanced current in the “on” state, also known as drive current. These advantages translate to lower power consumption and enhanced device performance. Nonplanar devices are also more compact than conventional planar transistors, enabling higher transistor density which translates to smaller overall microelectronics.

However, there are still some drawbacks and disadvantages in conventional multi-gate transistors. For example, the active region of the conventional transistor does not extend beyond the bend around portion of the gate lines, so the ends of the drain/source fingers can not contribute as part of the conduction channel to increase the channel conductance of the transistor. In addition, the conventional multi-gate transistor also has isolation issue to overcome.

Therefore, the invention provides a full periphery multi-gate transistor with ohmic strip to solve the above-mentioned problems.

### SUMMARY OF THE INVENTION

A main scope of the invention is to provide a full periphery multi-gate transistor with ohmic strip. An embodiment according to the invention is a multi-gate transistor. In this embodiment, the multi-gate transistor comprises a substrate, a multi-layer structure, a source finger, a drain finger, and a gate. The multi-layer structure is formed upon the substrate. The source finger and the drain finger are both formed upon the multi-layer structure. The gate is formed between the source finger and the drain finger, and then a conduction channel will be formed between the source finger and the drain finger. The gate also wraps meanderingly around one end of the source finger and one end of the drain finger, so that the end of the source finger and the end of the drain finger can be parts of the conduction channel and both provide some channel conductance. It should be noticed that a pattern having round/curved corners is used for the routing of the gate.

In practical applications, the gate of the multi-gate transistor will comprise N gate lines, wherein N is a positive integer larger than 1. For example, if N=2, the transistor will be a dual-gate transistor; if N=3, the transistor will be a triple-gate transistor, and so on. In order to provide a connection to the potential balance resistors between the source finger and the drain finger, the multi-gate transistor can further comprise (N-1) ohmic strips formed between every two of the N gate lines.

Another embodiment according to the invention is also a multi-gate transistor. In this embodiment, the multi-gate transistor comprises a substrate, a multi-layer structure, a source finger, a drain finger, a gate comprising N gate lines, and (N-1) ohmic strips, wherein N is a positive integer larger than 1. The multi-layer structure is formed upon the substrate. The source finger and the drain finger are both formed upon the multi-layer structure. The gate comprising N gate lines is formed between the source finger and the drain finger. The (N-1) ohmic strips are formed between every two of the N gate lines, and used for providing a connection to the potential balance resistors between the source finger and the drain finger.

Compared to the prior art, the full periphery multi-gate transistor with ohmic strip according to the invention not only extends the conduction channel of the transistor to the ends of the source/drain fingers to increase at least 10% channel conductance, but also provides a mean to connect the potential balance resistors between the source finger and the drain finger. Then, the isolation of the multiple gates can rival that of the multiple stacks, while still retaining the small size from a single device.

The advantage and spirit of the invention may be further understood by the following recitations together with the appended drawings.

### BRIEF DESCRIPTION OF THE APPENDED DRAWINGS

FIG. 1 shows a cross-sectional view of the multi-gate transistor in the first embodiment according to the invention.

FIG. 2 shows a top view of the dual-gate transistor of FIG. 1.

FIG. 3 shows a cross-sectional view of an example of the ohmic strip as a connector of the potential balance resistors.

### DETAILED DESCRIPTION OF THE INVENTION

The invention provides a full periphery multi-gate transistor with ohmic strip to extend the conduction channel of the transistor to the ends of the source/drain fingers and provide a mean to connect the potential balance resistors between the source finger and the drain finger. Therefore, the channel conductance will be largely enhanced and the isolation of the multiple gates can rival that of the multiple stacks, while still retaining the small size from a single device.

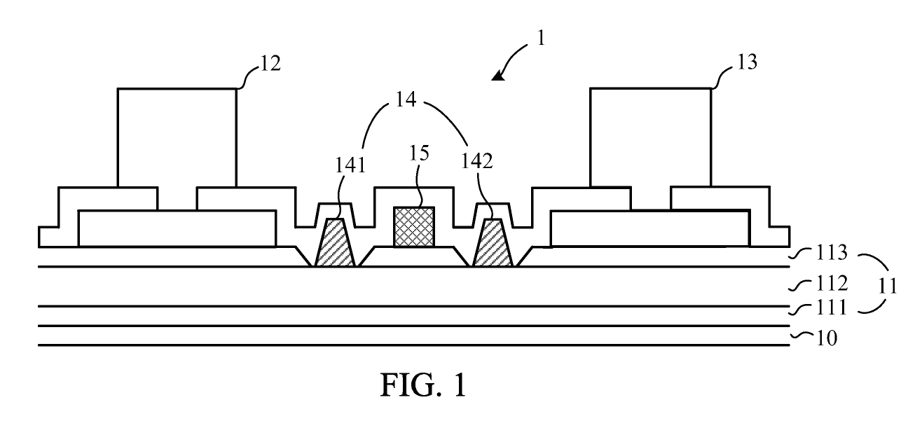

A first embodiment according to the invention is a dual-gate transistor. It should be noted that the invention is also applied to any other kinds of multiple-gate transistor, such as a triple-gate transistor, or a 5-gate transistor. Please refer to FIG. 1. FIG. 1 shows a cross-sectional view of the dual-gate transistor in the first embodiment according to the invention.

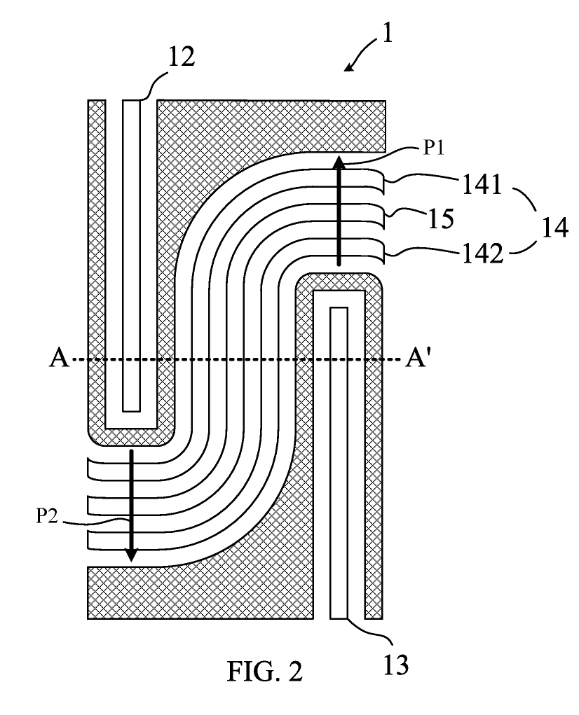

As shown in FIG. 1, the dual-gate transistor 1 comprises a substrate 10, a multi-layer structure 11, a source finger 12, a drain finger 13, and a gate 14. The gate 14 comprises a first gate line 141 and a second gate line 142. In fact, the substrate can be a silicon substrate, a GaAs substrate, an InP substrate, a SiGe substrate, a GaN substrate, a SiC substrate, or any other semiconductor substrates; the gate 14 can be, but not limited to, a metal gate. FIG. 2 shows the top view of the dual-gate transistor 1, and FIG. 1 is the cross-sectional view of the dual-gate transistor 1 along the AA′ line shown in FIG. 2. In the structure of dual-gate transistor 1, the multi-layer structure 11 is formed upon the substrate 10. In practical applications, the multi-layer structure 11 comprises a channel layer 111, a schottky layer 112, and a cap layer 113. Among these three layers, the channel layer 111 is formed upon the substrate 10, then the schottky layer 112 is formed upon the channel layer 111, and the cap layer 113 is formed upon the schottky layer 112. It should be noted that the structure of the multi-layer structure 11 can be other types of structure, not limited by this case.

In this embodiment, the source finger 12 and the drain finger 13 are both formed upon the multi-layer structure 11. The gate 14 is formed between the source finger 12 and the drain finger 13. A conduction channel will be formed between the source finger 12 and the drain finger 13, and the gate 14 will control whether a current can flow between the source finger 12 and the drain finger 13.

One of the features of this “full periphery” dual-gate transistor 1 is that the gate 14 also wraps meanderingly around one end 121 of the source finger 12 and one end 131 of the drain finger 13, so that the end 121 of the source finger 12 and the end 131 of the drain finger 13 can be parts of the conduction channel. In fact, when the gate 14 meanderingly wraps around the end 121 of the source finger 12 and the end 131 of the drain finger 13, a pattern having round/curved corners is used for the routing of the gate 14. However, the shape of the pattern can be in other forms, not limited by this case.

That is to say, the conduction channel of the dual-gate transistor 1 can be extended to the end 121 of the source finger 12 and the end 131 of the drain finger 13. Moreover, both of the end 121 of the source finger 12 and the end 131 of the drain finger 13 can provide some channel conductance, so that the channel conductance will increase at least 10% due to the effect of the “full periphery” dual-gate transistor 1. Moreover, additional conducting paths P1 and P2 are shown in FIG. 2. And, both of these additional conducting paths P1 and P2 can increase the channel conductance of the dual-gate transistor 1.

As shown in FIG. 2, it should be noticed that when the gate 14 wraps meanderingly around one end 121 of the source finger 12 and/or one end 131 of the drain finger 13, the gate 14 will be round or curved around the corners of the end 121 and/or the end 131. And, the gate 14 can be straight or curved between the corners. However, the shape of the gate 14 can be in other forms, not limited by these cases.

Another feature of this “full periphery” dual-gate transistor 1 is that the dual-gate transistor 1 has ohmic strip 15 between the first gate line 141 and the second gate line 142, as shown in FIG. 1. In general, if the gate 14 comprises N gate lines (N is a positive integer larger than 1), the N-gate transistor 1 will comprise (N-1) ohmic strips formed between every two of the N gate lines, and the ohmic strips are used for providing a connection to the potential balance resistors between the source finger 12 and the drain finger 13. In fact, the (N-1) ohmic strips can be composed of metal.

For example, if N=3, it means that the transistor 1 is a triple-gate transistor having a first ohmic strip and a second ohmic strip, and the multi-gate gate 14 has a first gate line, a second gate line, and a third gate line. The first ohmic strip is between the first gate line and the second gate line; the second ohmic strip is between the second gate line and the third gate line. And, N can also be 4, 5, . . . , and so on.

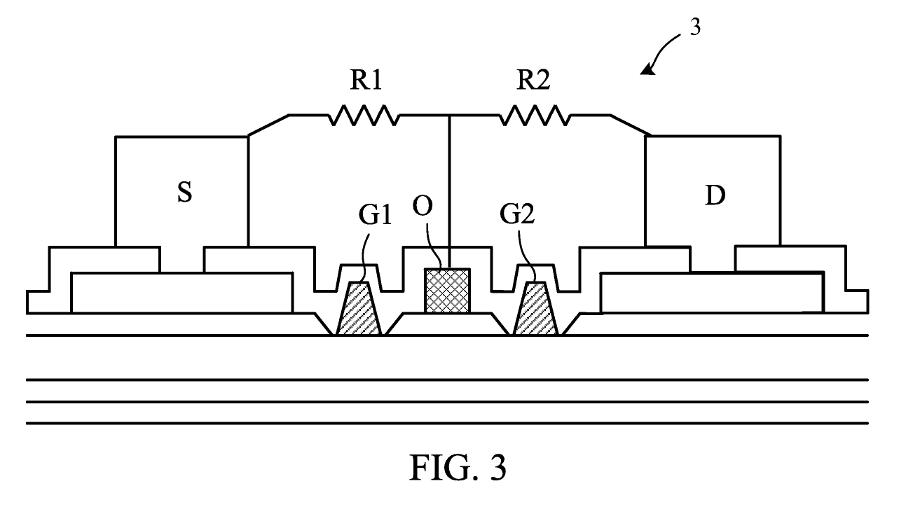

In this embodiment, the ohmic strip in the dual-gate transistor 1 provides a mean to connect the potential balance resistors between the source finger 12 and the drain finger 13. Please refer to FIG. 3, FIG. 3 shows an example of the ohmic strip as a connector of the potential balance resistors. As shown in FIG. 3, the multi-gate transistor 3 is a dual-gate transistor having a first gate line G1 and a second gate line G2 between the source S and the drain D. And, the multi-gate transistor 3 also has an ohmic strip O between the first gate line G1 and the second gate line G2.

It should be noted that there are two balance resistors R1, R2 between the source S and the drain D, and the ohmic strip O can provide a mean to connect the balance resistors R1 and R2, as shown in FIG. 3. By doing so, the isolation of the dual gates can rival that of the multiple stacks, while still retaining the small size from a single device.

Moreover, in a general dual-gate transistor, the fringe field coming from drain/source lines and gate lines is a big affecting factor in isolation. With the full periphery design according to the invention, the lines will become thinner, so the isolation under a high frequency (e.g., 5.5 GHz) condition will be improved.

In our experiment results, we find that no matter for a dual-gate transistor or a triple-gate transistor, if the transistor has the full periphery design, the transistor will maintain the same insertion loss, as long as the total active gate periphery is designed to be the same as the baseline design without the full periphery design.

Additionally, we also find from the experiment results that the dual-gate transistor with the ohmic strip design between the two gates has better power handling of the dual-gate than that of the dual-gate transistor without the ohmic strip design. For example, the power handling of the dual-gate can increase 1 dBm at 75 dBc harmonic ratio. Similar condition is also found from the experiment results of the triple-gate transistor w/o the ohmic strip design between every two gates.

A second embodiment according to the invention is also a multi-gate transistor. The cross-sectional view of the multi-gate transistor can also refer to FIG. 1. In this embodiment, the multi-gate transistor comprises a substrate, a multi-layer structure, a source finger, a drain finger, a gate comprising N gate lines, and (N-1) ohmic strips, wherein N is a positive integer larger than 1. The multi-layer structure is formed upon the substrate. The source finger and the drain finger are both formed upon the multi-layer structure. The gate comprising N gate lines is formed between the source finger and the drain finger. The (N-1) ohmic strips are formed between every two of the N gate lines, and used for providing a connection to the potential balance resistors between the source finger and the drain finger.

In practical applications, the substrate can be a silicon substrate, a GaAs substrate, an InP substrate, a SiGe substrate, a GaN substrate, a SiC substrate, or any other semiconductor substrates; the gate can be a metal gate; the (N-1) ohmic strips can be composed of metal; the multi-layer structure can comprise a channel layer, a schottky layer upon the channel layer, and a cap layer upon the schottky layer, but not limited by these cases.

It should be noted that in the multi-gate transistor of the second embodiment, the position of the multiple-gate has no limitation. For example, the multiple-gate can meanderingly wraps around an end of the source finger and an end of the drain finger just as the multiple-gate of the first embodiment does, or only formed between the source finger and the drain finger as the multiple-gate of prior art does.

In this embodiment, the ohmic strips in the multi-gate transistor can provide a mean to connect the potential balance resistors between the source finger and the drain finger. An example of the ohmic strip as a connector of the potential balance resistors can also refer to FIG. 3. Therefore, the isolation of the dual gates can rival that of the multiple stacks, while still retaining the small size from a single device.

Compared to the prior art, the full periphery multi-gate transistor with ohmic strip according to the invention can not only extends the conduction channel of the transistor to the ends of the source/drain fingers to increase at least 10% channel conductance, but also provides a mean to connect the potential balance resistors between the source finger and the drain finger. Then, the isolation of the multiple gates can rival that of the multiple stacks, while still retaining the small size from a single device. Moreover, in the full periphery multi-gate transistor with ohmic strip according to the invention, the gate-length, the on-resistance Rₒₙ, and the gate capacitance will be maintained to be uniform and consistent along the whole course of the gate meander.

With the recitations of the preferred embodiment above, the features and spirits of the invention will be hopefully well described. However, the scope of the invention is not restricted by the preferred embodiment disclosed above. The objective is that all alternative and equivalent arrangements are hopefully covered in the scope of the appended claims of the invention. Accordingly, the above disclosure should be construed as limited only by the metes and bounds of the appended claims.

What is claimed is:

1. A multi-gate transistor, comprising:
a substrate;
a multi-layer structure formed upon the substrate;
a source finger formed upon the multi-layer structure;
a drain finger formed upon the multi-layer structure; and
a gate formed between the source finger and the drain finger, then a conduction channel being formed between the source finger and the drain finger, the gate also meanderingly wrapping around an end of the source finger and an end of the drain finger;
wherein the end of the source finger and the end of the drain finger are parts of the conduction channel and both provide channel conductance.

2. The multi-gate transistor of claim 1, wherein the substrate is selected from a group of a silicon substrate, a GaAs substrate, an InP substrate, a SiGe substrate, a GaN substrate, and a SiC substrate.

3. The multi-gate transistor of claim 1, wherein the multi-layer structure comprises a channel layer, a schottky layer upon the channel layer, and a cap layer upon the schottky layer.

4. The multi-gate transistor of claim 1, wherein the gate is a metal gate.

5. The multi-gate transistor of claim 1, wherein the gate comprises N gate lines, N is a positive integer larger than 1.

6. The multi-gate transistor of claim 5, further comprising:
(N-1) ohmic strips, formed between every two of the N gate lines, for providing a connection to the potential balance resistors between the source finger and the drain finger.

7. The multi-gate transistor of claim 6, wherein the (N-1) ohmic strips are composed of metal.

8. The multi-gate transistor of claim 1, wherein when the gate meanderingly wraps around the end of the source finger and the end of the drain finger, a pattern having round/curved corners is used for the routing of the gate.

9. A multi-gate transistor, comprising:
a substrate;
a multi-layer structure formed upon the substrate;
a source finger formed upon the multi-layer structure;
a drain finger formed upon the multi-layer structure;
a gate comprising N gate lines, formed between the source finger and the drain finger, N being a positive integer larger than 1; and
(N-1) ohmic strips, formed between every two of the N gate lines, for providing a connection to the potential balance resistors between the source finger and the drain finger.

10. The multi-gate transistor of claim 9, wherein the substrate is selected from a group of a silicon substrate, a GaAs substrate, an InP substrate, a SiGe substrate, a GaN substrate, and a SiC substrate.

11. The multi-gate transistor of claim 9, wherein the multi-layer structure comprises a channel layer, a schottky layer upon the channel layer, and a cap layer upon the schottky layer.

12. The multi-gate transistor of claim 9, wherein the gate is a metal gate.

13. The multi-gate transistor of claim 9, wherein the (N-1) ohmic strips are composed of metal.
